(19) United States
(12) Patent Application Publication
(10) Pub. No.: US 2024/0204797 A1
(43) Pub. Date: Jun. 20, 2024

(54) SYSTEMS AND METHODS FOR ADAPTING PREDICTION MODELS BY COMPRESSING ENCODED DATA

(71) Applicant: Toyota Research Institute, Inc., Los Altos, CA (US)

(72) Inventors: Stephen G. McGill, JR., Havertown, PA (US); Guy Rosman, Newton, MA (US); Paul Drews, Watertown, MA (US)

(73) Assignees: Toyota Research Institute, Inc., Los Altos, CA (US); Toyota Jidosha Kabushiki Kaisha, Toyota-shi (JP)

(21) Appl. No.: 18/085,074

(22) Filed: Dec. 20, 2022

(51) Int. Cl. H03M 7/30; G06N 20/00; G08G 1/01

(52) U.S. Cl. CPC H03M 7/6005; G06N 20/00; G08G 1/0141

(57) ABSTRACT

System, methods, and other embodiments described herein relate to improving prediction models by compressing and sharing encoded data for partial scene representations about target vehicles. In one embodiment, a method includes receiving, by a subject vehicle, packets with compressed partial representations of a latent space associated with different views of target vehicles. The method also includes generating an attention vector about the different views by aggregating the packets for the target vehicles. The method also includes computing, by a prediction model, an addition vector that optimizes data decoding by the prediction model using acquired data from the attention vector. The method also includes training the prediction model using the addition vector to reduce data representations and adapt data compression associated with the latent space.

### TECHNICAL FIELD

The subject matter described herein relates, in general, to adapting prediction models using compression, and, more particularly, to adapting prediction models by compressing and sharing encoded data for partial scenes.

### BACKGROUND

Vehicles use wireless networks for sharing safety and traffic information. For example, vehicles form an ad-hoc vehicle-to-vehicle (V2V) network for executing various safety tasks. The information can include raw data from sensors that facilitate perceiving other vehicles, obstacles, pedestrians, and additional aspects of a surrounding environment. In one approach, a vehicle is equipped with a light detection and ranging (LIDAR) sensor that uses light to scan the surrounding environment, while logic associated with the LIDAR analyzes acquired data to detect the presence of objects and other features of the surrounding environment. In further examples, additional sensors such as cameras acquire information about the surrounding environment that vehicles use in models that predict environmental changes. Vehicles can use the predictions to plan and navigate a driving scenario accordingly.

In various implementations, information sharing through V2V communications allows vehicles to coordinate traffic and improve safety by increasing data diversity. Coordination includes communicating raw data from sensors for processing by a prediction model. In one approach, the raw data is compressed to reduce the load on V2V networks. However, systems encounter difficulties from lost details and errors when decompressing the raw data. Furthermore, vehicles using the raw data in models have scene information that is incomplete without context (e.g., accelerating vehicle, stopped vehicle, etc.) from the transmitting vehicles.

### SUMMARY

In one embodiment, example systems and methods relate to a manner of improving prediction models by compressing and sharing encoded data for partial scene representations about target vehicles. In various implementations, systems coordinating prediction using vehicle-to-vehicle (V2V) communications encounter difficulties when using raw data from sensors. For example, the raw data from a light detection and ranging (LIDAR) sensor describes the distance to an object without further context. Here, an object type (e.g., crossing vehicle, traffic light, etc.) and direction can provide coordinating vehicles a scene understanding for a prediction model. Therefore, in one embodiment, an assistance system processes packets from data encodings of a latent space including different views about target vehicles. In particular, vehicles process sensor data for the target vehicles using a prediction model and communicate encoded data associated with partial scenes selectively to other vehicles. Here, the encoded data can be trajectories, hazardous objects, and so on associated with the target vehicles. In one approach, the assistance system computes an addition vector reflecting parameters (e.g., mean, variance, etc.) of the encoded data that simplifies predictions.

In various implementations, the vehicles train the prediction model using the addition vector that effectively reduces representations within the latent space. As such, the addition vector adapts data compression while improving predictions using the different views and context for the target vehicles from the encoded data. Accordingly, the vehicles efficiently share computations for the latent space by communicating and aggregating the encoded data, thereby improving predictions for safety and traffic management.

In one embodiment, an assistance system for improving prediction models by compressing and sharing encoded data for partial scene representations about target vehicles is disclosed. The assistance system includes a processor and a memory storing instructions that, when executed by the processor cause the processor to receive, by a subject vehicle, packets with compressed partial representations of a latent space associated with different views of target vehicles. The instructions also include instructions to generate an attention vector about the different views by aggregating the packets for the target vehicles. The instructions also include instructions to compute, by a prediction model, an addition vector that optimizes data decoding by the prediction model using acquired data from the attention vector. The instructions also include instructions to train the prediction model using the addition vector to reduce data representations and adapt data compression associated with the latent space.

In one embodiment, a non-transitory computer-readable medium for improving prediction models by compressing and sharing encoded data for partial scene representations about target vehicles and including instructions that when executed by a processor cause the processor to perform one or more functions is disclosed. The instructions include instructions to receive, by a subject vehicle, packets with compressed partial representations of a latent space associated with different views of target vehicles. The instructions also include instructions to generate an attention vector about the different views by aggregating the packets for the target vehicles. The instructions also include instructions to compute, by a prediction model, an addition vector that optimizes data decoding by the prediction model using acquired data from the attention vector. The instructions also include instructions to train the prediction model using the addition vector to reduce data representations and adapt data compression associated with the latent space.

In one embodiment, a method for improving prediction models by compressing and sharing encoded data for partial scene representations about target vehicles is disclosed. In one embodiment, the method includes receiving, by a subject vehicle, packets with compressed partial representations of a latent space associated with different views of target vehicles. The method also includes generating an attention vector about the different views by aggregating the packets for the target vehicles. The method also includes computing, by a prediction model, an addition vector that optimizes data decoding by the prediction model using acquired data from the attention vector. The method also includes training the prediction model using the addition vector to reduce data representations and adapt data compression associated with the latent space.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a vehicle within which systems and methods disclosed herein may be implemented.

FIG. 2 illustrates one embodiment of an assistance system that compresses and shares encoded data about target vehicles.

FIG. 3 illustrates an example of a prediction model using the assistance system to reduce data representations and adapt compression for a latent space.

FIG. 4 illustrates an example of the assistance system using vehicle-to-vehicle (V2V) communications to share encoded data of target vehicles for training.

FIG. 5 illustrates one embodiment of a method that is associated with an assistance system that trains a prediction model to improve compression and reduce dimensionality.

### DETAILED DESCRIPTION

Systems, methods, and other embodiments associated with improving prediction models by compressing and sharing encoded data for partial scene representations about target vehicles are disclosed herein. In various implementations, systems sharing raw sensor data using vehicle-to-vehicle (V2V) communications for distributed predictions produce elementary estimates. For example, a light detection and ranging (LIDAR) sensor produces data that a system uses for distance computations. However, distance from objects (e.g., trees, buildings, vehicles, etc.) provides limited information for systems to understand a scene and compute predictions reliably. Therefore, in one embodiment, an assistance system in a vehicle processes packets received with partial representations of a latent space compressed by nearby vehicles. Here, the partial representations are encoded data about different views of target vehicles within a driving scene. In one approach, the assistance system generates an attention vector about the different views and the partial scene by aggregating the packets for view reconstruction. The attention vector includes enhanced data for reliable and key features of a view (e.g., low-interference color) while diminishing other characteristics. Furthermore, a prediction model computes an addition vector that optimizes data decoding using data from the attention vector that reduces network complexity.

In one approach, the assistance system aggregates addition vectors to train the prediction model for reducing data representations and improving data compression (e.g., reducing losses) for the latent space. For example, received samples for a target vehicle have a priority ranking when entering an intersection and lesser priority during an exit. In this way, the training reduces the dimensionality and losses of the data compression using compressed encodings from the latent space, addition vectors, and V2V communications. This also improves the reliability and efficiency of distributed predictions by using the aggregated views and encoded data about the target vehicles.

In various implementations, the assistance system adapts training of the prediction model by splitting the latent space. For example, the aggregation of the packets uses a quality factor for filtering encoded data about target vehicles. The assistance system can reduce processing associated with the latent space by filtering out driving scenarios that are common. Furthermore, the assistance system trains the prediction model to reduce dimensionality (e.g., feature bits compressed) and compression losses of acquired data from the addition vectors by factoring the driving scenarios, redundant views, view quality, and so on. Accordingly, the assistance system improves the training of a prediction model by aggregating encoded data about views of target vehicles while reducing compression losses, thereby increasing prediction reliability.

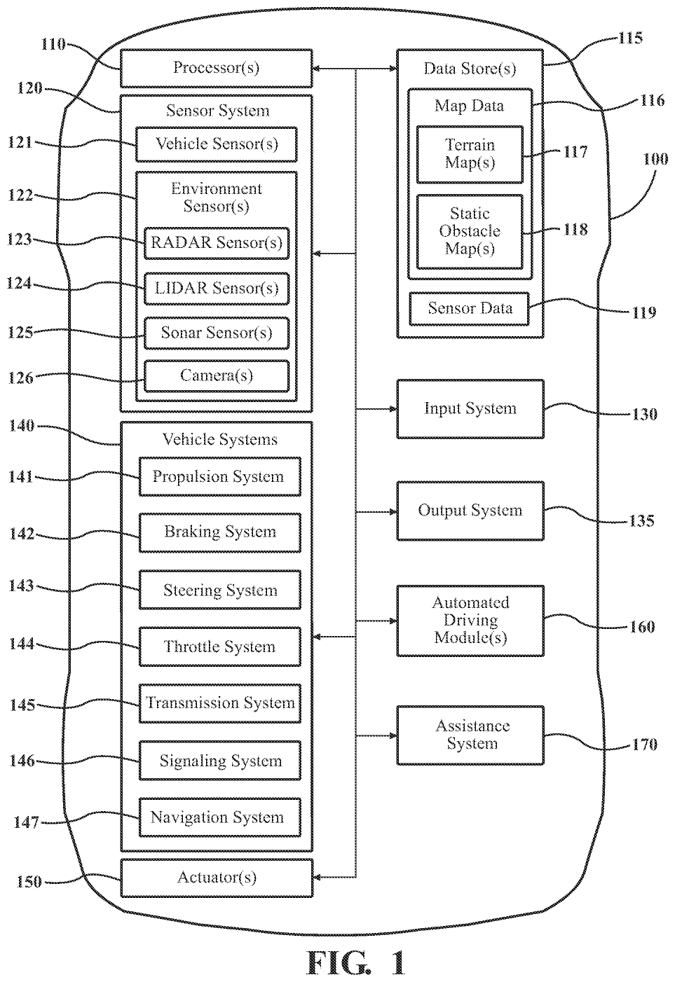

Referring to FIG. 1, an example of a vehicle 100 is illustrated. As used herein, a “vehicle” is any form of motorized transport. In one or more implementations, the vehicle 100 is an automobile. While arrangements will be described herein with respect to automobiles, it will be understood that embodiments are not limited to automobiles. In some implementations, an assistance system 170 uses road-side units (RSU), consumer electronics (CE), mobile devices, robots, drones, and so on that benefit from the functionality discussed herein associated with improving prediction models by compressing and sharing encoded data for partial scene representations about target vehicles.

The vehicle 100 also includes various elements. It will be understood that in various embodiments, the vehicle 100 may have less than the elements shown in FIG. 1. The vehicle 100 can have any combination of the various elements shown in FIG. 1. Furthermore, the vehicle 100 can have additional elements to those shown in FIG. 1. In some arrangements, the vehicle 100 may be implemented without one or more of the elements shown in FIG. 1. While the various elements are shown as being located within the vehicle 100 in FIG. 1, it will be understood that one or more of these elements can be located external to the vehicle 100. Furthermore, the elements shown may be physically separated by large distances. For example, one or more components of the disclosed system can be implemented within a vehicle while further components of the system are implemented within a cloud-computing environment or other system that is remote from the vehicle 100.

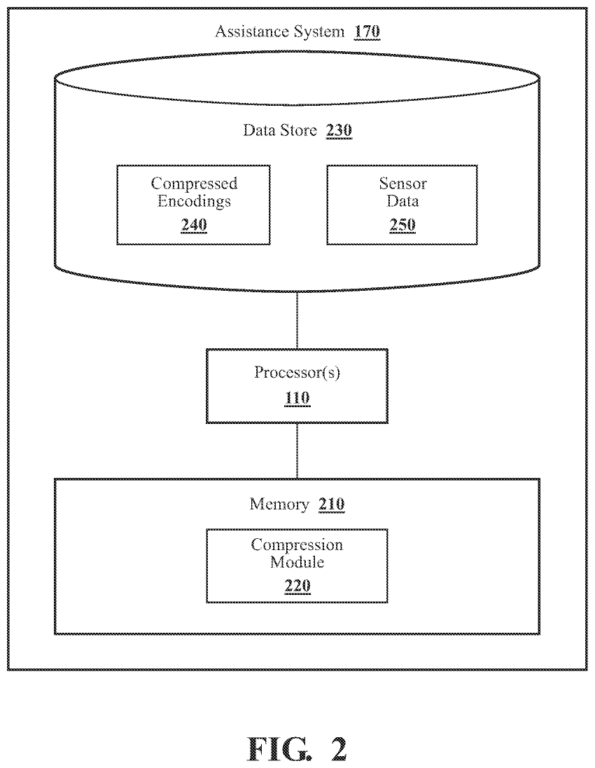

Some of the possible elements of the vehicle 100 are shown in FIG. 1 and will be described along with subsequent figures. However, a description of many of the elements in FIG. 1 will be provided after the discussion of FIGS. 2-5 for purposes of brevity of this description. Additionally, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements. In either case, the vehicle 100 includes an assistance system 170 that is implemented to perform methods and other functions as disclosed herein relating to improving prediction models by compressing and sharing encoded data for partial scene representations about target vehicles.

With reference to FIG. 2, one embodiment of the assistance system 170 of FIG. 1 is further illustrated. The assistance system 170 is shown as including a processor(s) 110 from the vehicle 100 of FIG. 1. Accordingly, the processor(s) 110 may be a part of the assistance system 170, the assistance system 170 may include a separate processor from the processor(s) 110 of the vehicle 100, or the assistance system 170 may access the processor(s) 110 through a data bus or another communication path. In one embodiment, the assistance system 170 includes a memory 210 that stores a compression module 220. The memory 210 is a random-access memory (RAM), a read-only memory (ROM), a hard-disk drive, a flash memory, or other suitable memory for storing the compression modules 220. The compression module 220 is, for example, computer-readable instructions that when executed by the processor(s) 110 cause the processor(s) 110 to perform the various functions disclosed herein. Furthermore, the assistance system 170 as illustrated in FIG. 2 is generally an abstracted form of the assistance system 170.

With reference to FIG. 2, the compression module 220 generally includes instructions that function to control the processor(s) 110 to receive data inputs from one or more sensors of the vehicle 100. The inputs are, in one embodiment, observations of one or more objects in an environment proximate to the vehicle 100 and/or other aspects about the surroundings. As provided for herein, the compression module 220, in one embodiment, acquires the sensor data 250 that includes at least camera images. In further arrangements, the compression module 220 acquires the sensor data 250 from further sensors such as radar sensors 123, LIDAR sensors 124, and other sensors suitable for identifying vehicles and locations of the vehicles.

Accordingly, the compression module 220, in one embodiment, controls the respective sensors to provide the data inputs in the form of the sensor data 250. Additionally, while the compression module 220 is discussed as controlling the various sensors to provide the sensor data 250, in one or more embodiments, the assistance system 170 can employ other techniques to acquire the sensor data 250 that are either active or passive. For example, the assistance system 170 may passively sniff the sensor data 250 from a stream of electronic information provided by the various sensors to further components within the vehicle 100. Moreover, the assistance system 170 can undertake various approaches to fuse data from multiple sensors when providing the sensor data 250 and/or from sensor data acquired over a wireless communication link. Thus, the sensor data 250, in one embodiment, represents a combination of perceptions acquired from multiple sensors.

Moreover, in one embodiment, the assistance system 170 includes the data store 230. In one embodiment, the data store 230 is a database. The database is, in one embodiment, an electronic data structure stored in the memory 210 or another data store and that is configured with routines that can be executed by the processor(s) 110 for analyzing stored data, providing stored data, organizing stored data, and so on. Thus, in one embodiment, the data store 230 stores data used by the compression module 220 in executing various functions. In one embodiment, the data store 230 includes the sensor data 250 along with, for example, metadata that characterize various aspects of the sensor data 250. For example, the metadata can include location coordinates (e.g., longitude and latitude), relative map coordinates or tile identifiers, time/date stamps from when the separate sensor data 250 was generated, and so on. In one embodiment, the data store 230 further includes the compressed encodings 240 that represent features (e.g., colors, shapes, objects, etc.) of a partial scene internal to a prediction model. For example, the compressed encodings 240 is an intermediate representation of perception data about a perspective as a vector. The vector can be a set having a mean, standard deviations (STD), variances, and so on about the perception data used to make inferences (e.g., trajectories) about objects. In another approach, the vector (e.g., 128 bits) includes samples from different perspectives that the vehicle 100 adds or concatenates to locally encoded data. In this way, the assistance system 170 forms a diverse distribution for training prediction models.

In one approach, the partial scene includes direct and obstructed views of the target vehicles. As such, the vehicle 100 aggregates encoded data having different views of the target vehicle to train prediction models for processing tasks using partial scenes. In particular, the prediction models may reconstruct elements of partial scenes to reliably perform tasks such as motion planning or object detection. As explained below, the assistance system 170 can aggregate encoded data by factoring common and specific driving scenarios involving target vehicles. In this way, the system trains a prediction model to use relevant data about driving scenarios while reducing dimensionality, thereby simplifying computations.

In various implementations, the vehicle 100 performs prediction tasks (e.g., motion planning) with the sensor data 250 and aggregated encoding involving target vehicles within the partial scene. As explained below, the assistance system 170 trains models using compression and decompression cycles and aggregates encodings to improve prediction efficiency. The assistance system 170 uses these cycles and aggregation for training a model (e.g., planning model, prediction model, etc.) about understanding different views and pertinent information for the target vehicles. In one approach, the assistance system 170 also trains a prediction model in real-time or online, thereby improving system adaptability and performance.

The compression module 220, in one embodiment, is further configured with instructions that cause the processor 110 to encode and compress the sensor data 250 (e.g., perception data). Here, the sensor data 250 includes common and pertinent views of target vehicles within the partial scene. A common view may be a scene region that a plurality of coordinating vehicles can acquire reliable data about the target vehicles. The vehicle 100 uses models (e.g., prediction, planning, etc.) that the assistance system 170 trains by extracting pertinent information from compression/decompression cycles. As explained below, such training can factor decompression losses that reduce prediction reliability. In this way, the assistance system 170 uses prediction models that generate an efficient representation of a latent space using compression, thereby saving bandwidth and improving coordination.

Moreover, the encoded and compressed data in one approach is associated with object location, tracking data, and so on for the target vehicles. For example, the encoded and compressed data is related to location, heading, future trajectories, and so on about an ego vehicle. In this way, the vehicle 100 aggregates encoded data instead of raw sensor data about the partial scene and trains a model for improved prediction while reducing computations.

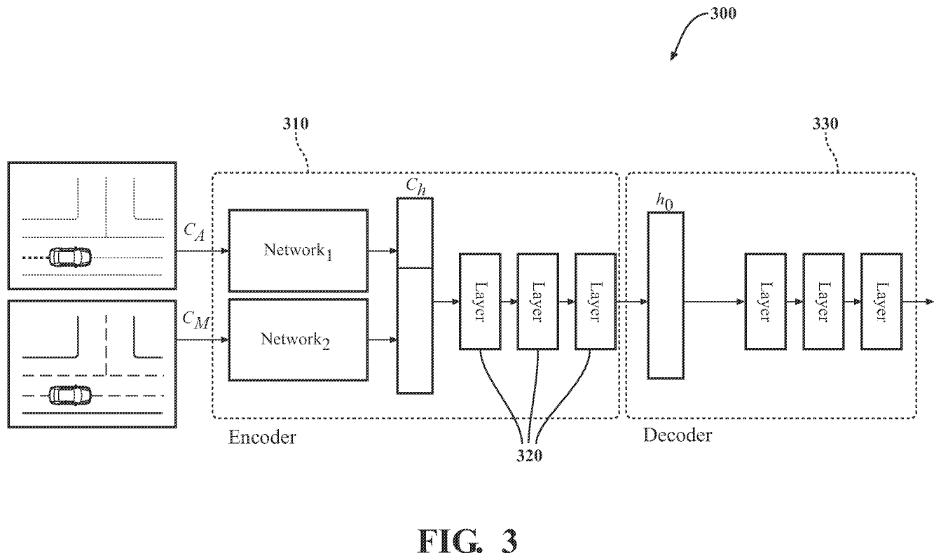

Turning now to FIG. 3, an example of a prediction model 300 using the assistance system 170 to reduce data representations and adapt compression internally for a latent space is illustrated. Here, the assistance system 170 or compression module 220 can extract the compressed encoding 240 from the layers 320 about a target vehicle for training the prediction model 300. For example, the compressed encoding 240 represents aggregated data about a partial scene acquired from nearby vehicles. The assistance system 170 aggregates the data to form diverse views about the target vehicle, thereby improving estimations (e.g., motion planning, object detection, etc.), error correction, and reducing computations by the prediction model 300. In other words, vehicles share compressed encodings to train prediction models for reconstructing the partial scene from aggregated viewpoints.

Moreover, the prediction model 300 includes an encoder 310 that processes an observed path of a target vehicle c_{A} and observed map data c_{M} using Network₁ and Network₂, respectively. The encoder 310 outputs a combined encoding state cₕ that represents observed path and map data perceived for the target vehicle. Here, the layers 320 process and compress the encoding state cₕ, such as through convolution operation layers for identifying salient attributes. Outputs of the layers 320 are intermediate activations from image data, feature maps, CAN data, past trajectories, velocity, angular velocity, and so on of the vehicle 100. The outputs may represent compressed encodings for the partial scene. As previously explained, compression may involve reducing per layer perception data about a perspective into a vector. The vector can be a set having a mean, standard deviations (STD), variances, and so on about the perception data used to compute inferences (e.g., trajectories) through feature decoding. Furthermore, the encoder 310 embeds c into a hidden state h₀ and the decoder 330 sample states conditioned on h₀ for completing predictions. For example, the predictions estimate a trajectory set having a small variance to a mean trajectory. The vehicle 100 may select and follow a trajectory from the set.

Regarding training details, the assistance system 170 decompresses the compressed encodings 240 received from other vehicles using the decoder 330. In this way, the vehicle 100 uses the prediction model 300 that is trained to understand representations by other vehicles about the target vehicle. For example, a nearby vehicle derives perceptions about pedestrians near an intersection crosswalk. As explained below, the vehicle 100 and the assistance system 170 can use an attention network to aggregate the derived perceptions about the crosswalk with other encodings and form an addition vector. The decoder 330 for the vehicle 100 trains to concatenate the addition vector to other data and predict a trajectory for a target vehicle accordingly. In one approach, the assistance system 170 fuses a concatenation vector to information available about a target vehicle. Correspondingly, the assistance system 170 during training leverages multiple estimations from points of view associated with different vehicles. The training can involve dropping in parallel (e.g., setting the concatenated vector to 0) randomly until training losses are minimized. As such, the assistance system 170 during implementation computes concatenated vectors when available and an attention field to average the input of different vehicles. In this way, the prediction model 300 processes reduced dimensionalities and improves compression performance.

Furthermore, the assistance system 170 acquires processed estimates for a target vehicle to train the prediction model 300. For example, a driving scenario involves the vehicle 100 and other vehicles observing a target vehicle approaching an intersection. The assistance system 170 receives packets having compressed encodings related to a trajectory, traffic light, and so on for a latent space. In one approach, the latent space is split by factoring a common and a specific scenario involving the target vehicle (e.g., 75% common and 25% specific). Here, aggregating views about the common scenarios has limited semantic value and quality since the vehicle 100 already has pertinent data for the target vehicle. However, the assistance system 170 can improve prediction models by learning through combining (e.g., concatenating) the specific scenarios from view limitations and data quality about the target vehicle.

In various implementations, the assistance system 170 optimizes internal compression by the prediction model 300 through training. Compressibility and decompression losses depend upon parameter types and distributions. For example, data compression varies between detecting an object and predicting trajectories. These differences can be reflected in sample distributions. Compression has increased efficiency when encoded data forms a Gaussian distribution since vehicles can simply communicate STDs/variances and the mean. Otherwise, compressibility is reduced when sending encoded samples instead of distributions in a vector (e.g., a vector set). The assistance system 170 processing encoded samples can also increase decompression losses, thereby impacting prediction reliability. As such, the assistance system 170 may improve prediction by training to process specific scenarios for the target vehicle having normal distributions. For instance, the assistance system 170 trains the prediction model to select received compression encodings from nearby vehicles that have a Gaussian distribution. Furthermore, as explained herein, selection may factor parameters associated with view quality, view obstructions, view redundancy, and so on of the target vehicle.

Moreover, the assistance system 170 reduces dimensionality for the bits processed by a compressor through the training. As such, the compressor operates using reduced representations through aggregating encodings having diverse data about the target vehicle. In one approach, vehicles in a driving scenario share the compressed encodings 240 using a hierarchy for adapting dimensionality. For example, the assistance system 170 trains the prediction model 300 to give data about vehicles that are approaching an intersection a priority ranking. On the contrary, vehicles leaving the intersection have a reduced ranking. In this way, the assistance system 170 improves the efficiency of the prediction model 300 while maintaining accuracy. Such priority rankings can also be factored during inference for the assistance system 170 to select processing of partial representations from the aggregated encodings.

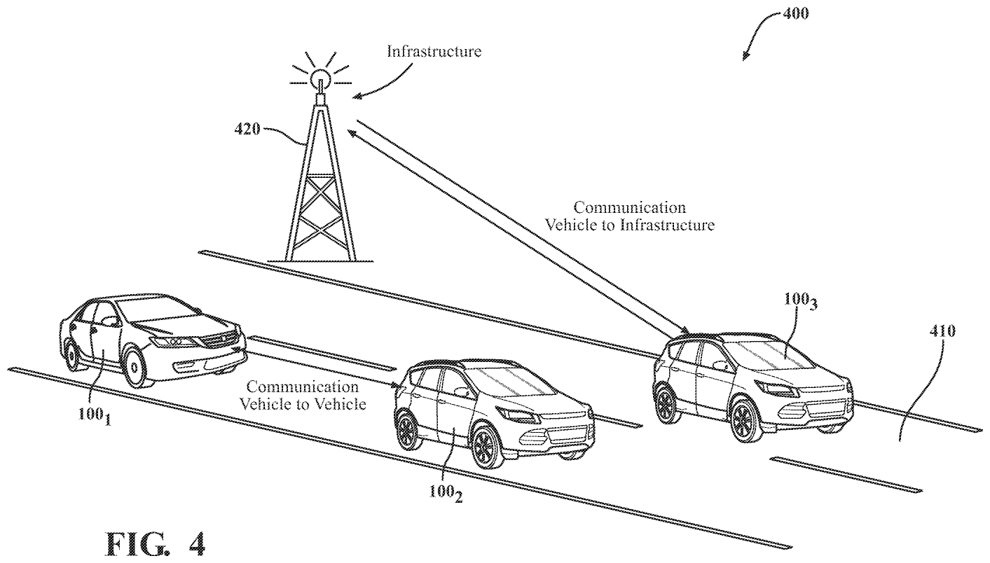

Turning now to FIG. 4, an example of the assistance system 170 using V2V communications to share encoded data of target vehicles for training and prediction is illustrated. In particular, vehicles in the driving scenario 400 improve compression and reduce the dimensionality of prediction models internally by sharing the compressed encodings 240. In this way, the assistance system 170 allows vehicles to process perception data with increased optimization. Here, the vehicles 100₁-100₃ are traveling on the road 410 in the driving scenario 400. The vehicle 100₃ is a target vehicle that communicates to the infrastructure 420 for motion planning, edge computing, cloud services, and so on. The assistance system 170 trains the vehicles 100₁ and 100₂ to leverage the compressed encodings 240 for prediction estimates about the vehicle 100₃. For example, both vehicles 100₁ and 100₂ are observing the vehicle 100₃ for vehicle tasks such as objection detection, cooperative prediction, and so on.

In various implementations, the vehicle 100₁ selects encoded data about specific scenarios and perceptions involving the vehicle 100₃. As previously explained, data from a specific scenario describing a narrow view about target vehicles can have more semantic value than a common scenario. In other words, the vehicle 100₁ has an enhanced view of the vehicle 100₃ compared to the vehicle 100₂, thereby making the compressed encodings 240 a valuable and pertinent candidate for sharing.

In the driving scenario 400, the vehicle 100₂ uses the compressed encodings 240 shared over V2V networks for training or inferences by a prediction model. As explained previously, the assistance system 170 may train the prediction model to concatenate the addition vector with processed data for feature decoding associated with the vehicle 100₃, such as during an intersection crossing. The addition vector may be derived from an attention vector generated by an attention network. The attention vector may include enhanced data for focused or key features of encoded perception data selected from nearby vehicles while diminishing other characteristics. In one approach, the addition vector has a distribution of samples (e.g., Gaussian) about an intermediate representation from different views of a target vehicle.

Moreover, the assistance system 170 can adapt the data compression through training according to object type, trajectories, and so on. In particular, vehicles share or process the compressed encoded 240 for scenarios that reduce compression losses or augment perception diversity. As previously explained, the assistance system 170 can similarly improve training and implementation by ranking samples from the addition vector using a hierarchy. For example, samples for the vehicle 100₃ have a priority ranking when entering an intersection and lesser priority during an exit. In this way, the training reduces dimensionality and losses of the data compression using the compressed encodings 240, addition vectors, and V2V communications.

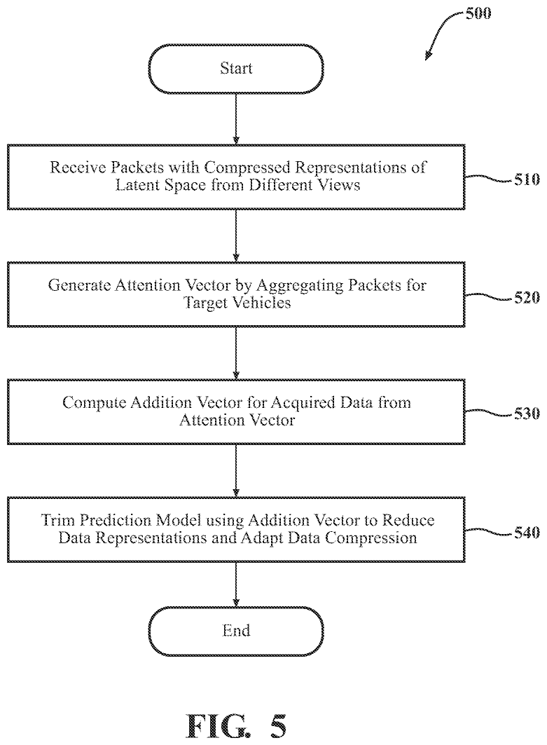

Now turning to FIG. 5, a flowchart of a method 500 that is associated with an assistance system that trains a prediction model to improve compression and reduce dimensionality is illustrated. Method 500 will be discussed from the perspective of the assistance system 170 of FIGS. 1 and 2. While method 500 is discussed in combination with the assistance system 170, it should be appreciated that the method 500 is not limited to being implemented within the assistance system 170 but is instead one example of a system that may implement the method 500.

At 510, the vehicle 100 receives packets with compressed representations of a latent space from different views. Here, the packets can be the compressed encodings 240 from a nearby vehicle(s) having pertinent or specific data (e.g., views) about target vehicles. The packets are partial representations about a latent space in that the perception data may reflect a specific scenario. As previously explained, a specific scenario can describe a limited view about the target vehicles and comprise more semantic value than a common scenario. Furthermore, the compressed encodings 240 may be generated by the nearby vehicle(s) using an attention network. In this way, the assistance system 170 identifies specific or particular scenarios for target vehicles that are valuable for cooperative prediction or other tasks.

At 520, the assistance system 170 generates an attention vector by aggregating packets for the target vehicles. An attention network generates the attention vector about the different views and a partial scene by aggregating the packets for data reconstruction. Here, as previously explained, the attention vector includes enhanced data for key features about encoded perception data involving the target vehicles while diminishing other characteristics. Furthermore, the assistance system 170 aggregates the packets to form diverse and complete views about the target vehicles. In this way, the prediction model trains to produce improved estimations (e.g., motion planning, object detection, etc.) and reduce compression errors. In particular, the prediction model reconstructs the partial scene from aggregated viewpoints having data about specific scenarios.

At 530, the compression module 220 computes an addition vector for acquired data from the attention vector. Here, the addition vector may be data about the partial scene or representation. In particular, the addition vector can have a distribution of samples (e.g., Gaussian) about an intermediate representation from different views of the target vehicles. As previously explained, the addition vector optimizes decoding using the distribution and through factoring ranked packets. For example, the assistance system 170 selects packets for the partial scene that reduce decompression losses according to rank and the distribution relative to the target vehicles. For example, samples for about the target vehicles are assigned priority rankings when entering an intersection and lesser priority during an exit by the assistance system 170. In this way, the prediction model reconstructs partial scenes efficiently and reliably to perform downstream tasks by the vehicle 100 (e.g., motion planning, object detection, etc.).

At 540, the assistance system 170 trains the prediction model using the addition vector to reduce (e.g., trim) data representations and adapt data compression. Here, the assistance system 170 decompresses the compressed encodings 240 received from other vehicles using a decoder. In particular, the vehicle 100 trains the prediction model to understand and process representations by other vehicles about the target vehicles. For example, a nearby vehicle derives atypical perceptions about cyclists and vehicles near an intersection. The assistance system 170 trains the prediction model so that an attention network factors the remote perceptions, such as through an addition vector, for partial scene representations. In one approach, the decoder 330 for the vehicle 100 concatenates the addition vector to other data and efficiently predicts trajectories for target vehicles accordingly.

Moreover, the assistance system 170 can train the prediction model for improved compressibility performance by factoring parameter types and distributions. As previously explained, data compression varies between object detection and trajectory predictions. Compression may achieve efficiency when encoded data forms a normal distribution (e.g., Gaussian). This distribution allows vehicles to compactly communicate STDs/variances and the mean instead of encoded samples. Here, compressibility is reduced when communicating encoded samples because of non-conformity and increased vector sizes. The assistance system 170 processing encoded samples can also increase decompression losses from communication errors. Losses and errors reduce prediction reliability by the prediction model. As such, the assistance system 170 may improve prediction by training to process specific scenarios for the target vehicle having normal distributions.

In various implementations, the assistance system 170 trains the prediction model to reduce dimensionality for the bits processed by a compressor. In particular, the compressor operates using reduced representations through aggregating encodings having diverse and atypical data about the target vehicles. As previously explained, vehicles in a driving scenario can share the compressed encodings 240 using a hierarchy based on quality factors (e.g., error rate). For example, the assistance system 170 trains the prediction model to process or share data about vehicles that are approaching an intersection, such as through a priority ranking. On the contrary, vehicles leaving the intersection have a reduced ranking. In this way, the assistance system 170 improves the efficiency of the prediction model while maintaining accuracy through training by prioritizing data.

FIG. 1 will now be discussed in full detail as an example environment within which the system and methods disclosed herein may operate. In some instances, the vehicle 100 is configured to switch selectively between different modes of operation/control according to the direction of one or more modules/systems of the vehicle 100. In one approach, the modes include: 0, no automation; 1, driver assistance; 2, partial automation; 3, conditional automation; 4, high automation; and 5, full automation. In one or more arrangements, the vehicle 100 can be configured to operate in a subset of possible modes.

In one or more embodiments, the vehicle 100 is an automated or autonomous vehicle. As used herein, “autonomous vehicle” refers to a vehicle that is capable of operating in an autonomous mode (e.g., category 5, full automation). “Automated mode” or “autonomous mode” refers to navigating and/or maneuvering the vehicle 100 along a travel route using one or more computing systems to control the vehicle 100 with minimal or no input from a human driver. In one or more embodiments, the vehicle 100 is highly automated or completely automated. In one embodiment, the vehicle 100 is configured with one or more semi-autonomous operational modes in which one or more computing systems perform a portion of the navigation and/or maneuvering of the vehicle along a travel route, and a vehicle operator (i.e., driver) provides inputs to the vehicle to perform a portion of the navigation and/or maneuvering of the vehicle 100 along a travel route.

The vehicle 100 can include one or more processors 110. In one or more arrangements, the processor(s) 110 can be a main processor of the vehicle 100. For instance, the processor(s) 110 can be an electronic control unit (ECU), an application-specific integrated circuit (ASIC), a microprocessor, etc. The vehicle 100 can include one or more data stores 115 for storing one or more types of data. The data store(s) 115 can include volatile and/or non-volatile memory. Examples of suitable data stores 115 include RAM, flash memory, ROM, programmable read-only memory (PROM), erasable programmable read-only memory (EPROM), electrically erasable programmable read-only memory (EEPROM), registers, magnetic disks, optical disks, and hard drives. The data store(s) 115 can be a component of the processor(s) 110, or the data store(s) 115 can be operatively connected to the processor(s) 110 for use thereby. The term “operatively connected,” as used throughout this description, can include direct or indirect connections, including connections without direct physical contact.

In one or more arrangements, the one or more data stores 115 can include map data 116. The map data 116 can include maps of one or more geographic areas. In some instances, the map data 116 can include information or data on roads, traffic control devices, road markings, structures, features, and/or landmarks in the one or more geographic areas. The map data 116 can be in any suitable form. In some instances, the map data 116 can include aerial views of an area. In some instances, the map data 116 can include ground views of an area, including 360-degree ground views. The map data 116 can include measurements, dimensions, distances, and/or information for one or more items included in the map data 116 and/or relative to other items included in the map data 116. The map data 116 can include a digital map with information about road geometry.

In one or more arrangements, the map data 116 can include one or more terrain maps 117. The terrain map(s) 117 can include information about the terrain, roads, surfaces, and/or other features of one or more geographic areas. The terrain map(s) 117 can include elevation data in the one or more geographic areas. The terrain map(s) 117 can define one or more ground surfaces, which can include paved roads, unpaved roads, land, and other things that define a ground surface.

In one or more arrangements, the map data 116 can include one or more static obstacle maps 118. The static obstacle map(s) 118 can include information about one or more static obstacles located within one or more geographic areas. A “static obstacle” is a physical object whose position does not change or substantially change over a period of time and/or whose size does not change or substantially change over a period of time. Examples of static obstacles can include trees, buildings, curbs, fences, railings, medians, utility poles, statues, monuments, signs, benches, furniture, mailboxes, large rocks, or hills. The static obstacles can be objects that extend above ground level. The one or more static obstacles included in the static obstacle map(s) 118 can have location data, size data, dimension data, material data, and/or other data associated with it. The static obstacle map(s) 118 can include measurements, dimensions, distances, and/or information for one or more static obstacles. The static obstacle map(s) 118 can be high quality and/or highly detailed. The static obstacle map(s) 118 can be updated to reflect changes within a mapped area.

One or more data stores 115 can include sensor data 119. In this context, “sensor data” means any information about the sensors that the vehicle 100 is equipped with, including the capabilities and other information about such sensors. As will be explained below, the vehicle 100 can include the sensor system 120. The sensor data 119 can relate to one or more sensors of the sensor system 120. As an example, in one or more arrangements, the sensor data 119 can include information about one or more LIDAR sensors 124 of the sensor system 120.

In some instances, at least a portion of the map data 116 and/or the sensor data 119 can be located in one or more data stores 115 located onboard the vehicle 100. Alternatively, or in addition, at least a portion of the map data 116 and/or the sensor data 119 can be located in one or more data stores 115 that are located remotely from the vehicle 100.

As noted above, the vehicle 100 can include the sensor system 120. The sensor system 120 can include one or more sensors. “Sensor” means a device that can detect, and/or sense something. In at least one embodiment, the one or more sensors detect, and/or sense in real-time. As used herein, the term “real-time” means a level of processing responsiveness that a user or system senses as sufficiently immediate for a particular process or determination to be made, or that enables the processor to keep up with some external process.

In arrangements in which the sensor system 120 includes a plurality of sensors, the sensors may function independently or two or more of the sensors may function in combination. The sensor system 120 and/or the one or more sensors can be operatively connected to the processor(s) 110, the data store(s) 115, and/or another element of the vehicle 100. The sensor system 120 can produce observations about a portion of the environment of the vehicle 100 (e.g., nearby vehicles).

The sensor system 120 can include any suitable type of sensor. Various examples of different types of sensors will be described herein. However, it will be understood that the embodiments are not limited to the particular sensors described. The sensor system 120 can include one or more vehicle sensors 121. The vehicle sensor(s) 121 can detect information about the vehicle 100 itself. In one or more arrangements, the vehicle sensor(s) 121 can be configured to detect position and orientation changes of the vehicle 100, such as, for example, based on inertial acceleration. In one or more arrangements, the vehicle sensor(s) 121 can include one or more accelerometers, one or more gyroscopes, an inertial measurement unit (IMU), a dead-reckoning system, a global navigation satellite system (GNSS), a global positioning system (GPS), a navigation system 147, and/or other suitable sensors. The vehicle sensor(s) 121 can be configured to detect one or more characteristics of the vehicle 100 and/or a manner in which the vehicle 100 is operating. In one or more arrangements, the vehicle sensor(s) 121 can include a speedometer to determine a current speed of the vehicle 100.

Alternatively, or in addition, the sensor system 120 can include one or more environment sensors 122 configured to acquire data about an environment surrounding the vehicle 100 in which the vehicle 100 is operating. “Surrounding environment data” includes data about the external environment in which the vehicle is located or one or more portions thereof. For example, the one or more environment sensors 122 can be configured to sense obstacles in at least a portion of the external environment of the vehicle 100 and/or data about such obstacles. Such obstacles may be stationary objects and/or dynamic objects. The one or more environment sensors 122 can be configured to detect other things in the external environment of the vehicle 100, such as, for example, lane markers, signs, traffic lights, traffic signs, lane lines, crosswalks, curbs proximate the vehicle 100, off-road objects, etc.

Various examples of sensors of the sensor system 120 will be described herein. The example sensors may be part of the one or more environment sensors 122 and/or the one or more vehicle sensors 121. However, it will be understood that the embodiments are not limited to the particular sensors described.

As an example, in one or more arrangements, the sensor system 120 can include one or more of: radar sensors 123, LIDAR sensors 124, sonar sensors 125, weather sensors, haptic sensors, locational sensors, and/or one or more cameras 126. In one or more arrangements, the one or more cameras 126 can be high dynamic range (HDR) cameras, stereo, or infrared (IR) cameras.

The vehicle 100 can include an input system 130. An “input system” includes components or arrangement or groups thereof that enable various entities to enter data into a machine. The input system 130 can receive an input from a vehicle occupant. The vehicle 100 can include an output system 135. An “output system” includes one or more components that facilitate presenting data to a vehicle occupant.

The vehicle 100 can include one or more vehicle systems 140. Various examples of the one or more vehicle systems 140 are shown in FIG. 1. However, the vehicle 100 can include more, fewer, or different vehicle systems. It should be appreciated that although particular vehicle systems are separately defined, any of the systems or portions thereof may be otherwise combined or segregated via hardware and/or software within the vehicle 100. The vehicle 100 can include a propulsion system 141, a braking system 142, a steering system 143, a throttle system 144, a transmission system 145, a signaling system 146, and/or a navigation system 147. Any of these systems can include one or more devices, components, and/or a combination thereof, now known or later developed.

The navigation system 147 can include one or more devices, applications, and/or combinations thereof, now known or later developed, configured to determine the geographic location of the vehicle 100 and/or to determine a travel route for the vehicle 100. The navigation system 147 can include one or more mapping applications to determine a travel route for the vehicle 100. The navigation system 147 can include a global positioning system, a local positioning system, or a geolocation system.

The processor(s) 110, the assistance system 170, and/or the automated driving module(s) 160 can be operatively connected to communicate with the various vehicle systems 140 and/or individual components thereof. For example, returning to FIG. 1, the processor(s) 110 and/or the automated driving module(s) 160 can be in communication to send and/or receive information from the various vehicle systems 140 to control the movement of the vehicle 100. The processor(s) 110, the assistance system 170, and/or the automated driving module(s) 160 may control some or all of the vehicle systems 140 and, thus, may be partially or fully autonomous as defined by the society of automotive engineers (SAE) levels 0 to 5.

The processor(s) 110, the assistance system 170, and/or the automated driving module(s) 160 can be operatively connected to communicate with the various vehicle systems 140 and/or individual components thereof. For example, returning to FIG. 1, the processor(s) 110, the assistance system 170, and/or the automated driving module(s) 160 can be in communication to send and/or receive information from the various vehicle systems 140 to control the movement of the vehicle 100. The processor(s) 110, the assistance system 170, and/or the automated driving module(s) 160 may control some or all of the vehicle systems 140.

The processor(s) 110, the assistance system 170, and/or the automated driving module(s) 160 may be operable to control the navigation and maneuvering of the vehicle 100 by controlling one or more of the vehicle systems 140 and/or components thereof. For instance, when operating in an autonomous mode, the processor(s) 110, the assistance system 170, and/or the automated driving module(s) 160 can control the direction and/or speed of the vehicle 100. The processor(s) 110, the assistance system 170, and/or the automated driving module(s) 160 can cause the vehicle 100 to accelerate, decelerate, and/or change direction. As used herein, “cause” or “causing” means to make, force, compel, direct, command, instruct, and/or enable an event or action to occur or at least be in a state where such event or action may occur, either in a direct or indirect manner.

The vehicle 100 can include one or more actuators 150. The actuators 150 can be an element or a combination of elements operable to alter one or more of the vehicle systems 140 or components thereof responsive to receiving signals or other inputs from the processor(s) 110 and/or the automated driving module(s) 160. For instance, the one or more actuators 150 can include motors, pneumatic actuators, hydraulic pistons, relays, solenoids, and/or piezoelectric actuators, just to name a few possibilities.

The vehicle 100 can include one or more modules, at least some of which are described herein. The modules can be implemented as computer-readable program code that, when executed by a processor(s) 110, implement one or more of the various processes described herein. One or more of the modules can be a component of the processor(s) 110, or one or more of the modules can be executed on and/or distributed among other processing systems to which the processor(s) 110 is operatively connected. The modules can include instructions (e.g., program logic) executable by one or more processors 110. Alternatively, or in addition, one or more data stores 115 may contain such instructions.

In one or more arrangements, one or more of the modules described herein can include artificial intelligence elements, e.g., neural network, fuzzy logic, or other machine learning algorithms. Furthermore, in one or more arrangements, one or more of the modules can be distributed among a plurality of the modules described herein. In one or more arrangements, two or more of the modules described herein can be combined into a single module.

The vehicle 100 can include one or more automated driving modules 160. The automated driving module(s) 160 can be configured to receive data from the sensor system 120 and/or any other type of system capable of capturing information relating to the vehicle 100 and/or the external environment of the vehicle 100. In one or more arrangements, the automated driving module(s) 160 can use such data to generate one or more driving scene models. The automated driving module(s) 160 can determine position and velocity of the vehicle 100. The automated driving module(s) 160 can determine the location of obstacles, obstacles, or other environmental features including traffic signs, trees, shrubs, neighboring vehicles, pedestrians, etc.

The automated driving module(s) 160 can be configured to receive, and/or determine location information for obstacles within the external environment of the vehicle 100 for use by the processor(s) 110, and/or one or more of the modules described herein to estimate position and orientation of the vehicle 100, vehicle position in global coordinates based on signals from a plurality of satellites, or any other data and/or signals that could be used to determine the current state of the vehicle 100 or determine the position of the vehicle 100 with respect to its environment for use in either creating a map or determining the position of the vehicle 100 in respect to map data.

The automated driving module(s) 160 either independently or in combination with the assistance system 170 can be configured to determine travel path(s), current autonomous driving maneuvers for the vehicle 100, future autonomous driving maneuvers and/or modifications to current autonomous driving maneuvers based on data acquired by the sensor system 120, driving scene models, and/or data from any other suitable source such as determinations from the sensor data 250. “Driving maneuver” means one or more actions that affect the movement of a vehicle. Examples of driving maneuvers include: accelerating, decelerating, braking, turning, moving in a lateral direction of the vehicle 100, changing travel lanes, merging into a travel lane, and/or reversing, just to name a few possibilities. The automated driving module(s) 160 can be configured to implement determined driving maneuvers. The automated driving module(s) 160 can cause, directly or indirectly, such autonomous driving maneuvers to be implemented. As used herein, “cause” or “causing” means to make, command, instruct, and/or enable an event or action to occur or at least be in a state where such event or action may occur, either in a direct or indirect manner. The automated driving module(s) 160 can be configured to execute various vehicle functions and/or to transmit data to, receive data from, interact with, and/or control the vehicle 100 or one or more systems thereof (e.g., one or more of vehicle systems 140).

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-5 but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein.

The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an ASIC, a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the present arrangements may be written in any combination of one or more programming languages, including an object-oriented programming language such as Java™, Smalltalk™, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. An assistance system comprising:
a processor; and
a memory storing instructions that, when executed by the processor, cause the processor to:
receive, by a subject vehicle, packets with compressed partial representations of a latent space associated with different views of target vehicles;
generate an attention vector about the different views by aggregating the packets for the target vehicles;
compute, by a prediction model, an addition vector that optimizes data decoding by the prediction model using acquired data from the attention vector; and
train the prediction model using the addition vector to reduce data representations and adapt data compression associated with the latent space.

2. The assistance system of claim 1, wherein the instructions to train the prediction model further include instructions to adapt the prediction model by concatenation of the addition vector to processed data for feature decoding associated with the target vehicles during an intersection crossing.

3. The assistance system of claim 1, further including instructions to aggregate, by the subject vehicle, the packets by splitting the latent space using a quality factor associated with the different views of one of the target vehicles.

4. The assistance system of claim 1, wherein the instructions to train the prediction model further include instructions to reduce dimensionality and losses of the data compression using the addition vector.

5. The assistance system of claim 1, wherein the addition vector has an intermediate representation reflected by samples from the different views and the different views form a statistical distribution.

6. The assistance system of claim 1, wherein the addition vector has an intermediate representation reflected by a mean and a variance from a Gaussian model of the acquired data.

7. The assistance system of claim 1, further including instructions to adapt the data compression according to the prediction model detecting one of an object and trajectories associated with the target vehicles.

8. The assistance system of claim 1, further including instructions to rank, by nearby vehicles, samples from the addition vector within a hierarchy according to the target vehicles approaching an intersection including the nearby vehicles.

9. The assistance system of claim 1, wherein the packets are intermediate data encoded by the prediction model and include trajectory data associated with the target vehicles.

10. A non-transitory computer-readable medium comprising:
instructions that when executed by a processor cause the processor to:
receive, by a subject vehicle, packets with compressed partial representations of a latent space associated with different views of target vehicles;
generate an attention vector about the different views by aggregating the packets for the target vehicles;
compute, by a prediction model, an addition vector that optimizes data decoding by the prediction model using acquired data from the attention vector; and
train the prediction model using the addition vector to reduce data representations and adapt data compression associated with the latent space.

11. The non-transitory computer-readable medium of claim 10, wherein the instructions to train the prediction model further include instructions to adapt the prediction model by concatenation of the addition vector to processed data for feature decoding associated with the target vehicles during an intersection crossing.

12. A method comprising:
receiving, by a subject vehicle, packets with compressed partial representations of a latent space associated with different views of target vehicles;
generating an attention vector about the different views by aggregating the packets for the target vehicles;
computing, by a prediction model, an addition vector that optimizes data decoding by the prediction model using acquired data from the attention vector; and
training the prediction model using the addition vector to reduce data representations and adapt data compression associated with the latent space.

13. The method of claim 12, wherein training the prediction model further includes adapting the prediction model by concatenating the addition vector to processed data for feature decoding associated with the target vehicles during an intersection crossing.

14. The method of claim 12, further comprising:
aggregating, by the subject vehicle, the packets by splitting the latent space using a quality factor associated with the different views of one of the target vehicles.

15. The method of claim 12, wherein training the prediction model further includes reducing dimensionality and losses of the data compression using the addition vector.

16. The method of claim 12, wherein the addition vector has an intermediate representation reflected by samples from the different views and the different views form a statistical distribution.

17. The method of claim 12, wherein the addition vector has an intermediate representation reflected by a mean and a variance from a Gaussian model of the acquired data.

18. The method of claim 12, further comprising:
adapting the data compression according to the prediction model detecting one of an object and trajectories associated with the target vehicles.

19. The method of claim 12, further comprising ranking, by nearby vehicles, samples from the addition vector within a hierarchy according to the target vehicles approaching an intersection including the nearby vehicles.

20. The method of claim 12, wherein the packets are intermediate data encoded by the prediction model and include trajectory data associated with the target vehicles.
